(19) United States
(12) Patent Application Publication
(10) Pub. No.: US 2023/0170341 A1
(43) Pub. Date: Jun. 1, 2023

(54) OPTOELECTRONIC COMPONENT AND METHOD FOR PRODUCING AN OPTOELECTRONIC COMPONENT

(71) Applicant: ams-OSRAM International GmbH, Regensburg (DE)

(72) Inventor: Daniel RICHTER, Bad Abbach (DE)

(21) Appl. No.: 17/921,726

(22) PCT Filed: Apr. 28, 2021
(86) PCT No.: PCT/EP2021/061079

§ 371 Date: Oct. 27, 2022

(30) Foreign Application Priority Data
May 4, 2020 (DE) 10 2020 205 592.0

(51) Int. Cl. H01L 25/16; H01L 25/075; H01L 33/62

(52) U.S. Cl. CPC H01L 25/167; H01L 25/0753; H01L 33/62; H01L 2933/0066

(57) ABSTRACT

An optoelectronic component includes a first molded body and a second molded body, which is separate from the first molded body. The optoelectronic component also includes a leadframe having a first leadframe section. The first leadframe section is embedded in some sections into the first molded body and in some sections into the second molded body. The first molded body has a cavity. A a first optoelectronic semiconductor chip is arranged in the cavity. An electronic semiconductor chip is arranged in or on the second molded body. The first optoelectronic semiconductor chip and the electronic semiconductor chip are each electrically conductively connected to the first leadframe section. The electronic semiconductor chip is configured to drive the first optoelectronic semiconductor chip.

The present invention relates to an optoelectronic component and to a method for producing an optoelectronic component.

The patent application claims the priority of German patent application 10 2020 205 592.0, the disclosure content of which is hereby incorporated by reference.

Optoelectronic components comprising optoelectronic semiconductor chips are known from the prior art. Optoelectronic components are known which can emit electromagnetic radiation in a direction parallel to a mounting plane. It is likewise known, in the case of optoelectronic components, to integrate further electronic semiconductor chips besides optoelectronic semiconductor chips.

One object of the present invention is to provide an optoelectronic component. A further object of the present invention is to specify a method for producing an optoelectronic component. These objects are achieved by means of an optoelectronic component and by means of a method for producing an optoelectronic component having the features of the independent claims. Various developments are specified in the dependent claims.

An optoelectronic component comprises a first molded body and a second molded body, which is separate from the first molded body, and also a leadframe comprising a first leadframe section. The first leadframe section is embedded in some sections into the first molded body and in some sections into the second molded body.

Advantageously, the first molded body and the second molded body of this optoelectronic component can accommodate different component parts of the optoelectronic component. In this case, an electrically conductive connection mediated by the first leadframe section can exist between said component parts. The separate configuration of the first molded body and the second molded body advantageously allows the first molded body and the second molded body of the optoelectronic component to be oriented independently of one another.

In one embodiment of the optoelectronic component, the first leadframe section has at least one bend between the first molded body and the second molded body. Such a bend advantageously allows the first molded body to be arranged with a different spatial orientation than the second molded body.

In one embodiment of the optoelectronic component, a first section of the first leadframe section, said first section being embedded into the first molded body, and a second section of the first leadframe section, said second section being embedded into the second molded body, are oriented at an angle different than 0° with respect to one another, in particular an angle of 90°. This advantageously enables the second molded body to be oriented perpendicular to the first molded body. As a result, the first molded body of the optoelectronic component can be oriented for example perpendicular to a mounting plane of the optoelectronic component.

In one embodiment of the optoelectronic component, a contact section of the first leadframe section, said contact section being arranged between the first molded body and the second molded body, forms a first soldering contact of the optoelectronic component. The first soldering contact can serve for mechanically securing the optoelectronic component. The first soldering contact can also serve for electrically contacting the optoelectronic component.

In one embodiment of the optoelectronic component, a second leadframe section of the leadframe is embedded in some sections into the second molded body but is not embedded into the first molded body. The second leadframe section can serve for example for electrically linking component parts accommodated in the second molded body of the optoelectronic component.

In one embodiment of the optoelectronic component, a contact section of the second leadframe section forms a second soldering contact of the optoelectronic component. The second soldering contact can serve for mechanically securing the optoelectronic component. The second soldering contact can also serve for electrically contacting the optoelectronic component.

In one embodiment of the optoelectronic component, the first molded body has a cavity. In this case, a first optoelectronic semiconductor chip is arranged in the cavity. The first optoelectronic semiconductor chip can be for example a light emitting diode chip (LED chip). One advantage of the optoelectronic component is that the first molded body can be oriented such that electromagnetic radiation emitted by the first optoelectronic semiconductor chip is emitted in a desired direction.

In one embodiment of the optoelectronic component, an electronic semiconductor chip is arranged in or on the second molded body. By way of example, the electronic semiconductor chip can be arranged in a cavity provided in the second molded body. The electronic semiconductor chip can be for example a driver chip for driving an optoelectronic semiconductor chip of the optoelectronic component.

In one embodiment of the optoelectronic component, the first optoelectronic semiconductor chip and the electronic semiconductor chip are each electrically conductively connected to the first leadframe section. An electrically conductive connection between the electronic semiconductor chip and the first optoelectronic semiconductor chip then advantageously exists.

In one embodiment of the optoelectronic component, the electronic semiconductor chip is configured to drive the first optoelectronic semiconductor chip. In this case, the electronic semiconductor chip can be configured for example to control whether the first optoelectronic semiconductor chip emits electromagnetic radiation. The electronic semiconductor chip can also be configured to control a brightness of electromagnetic radiation emitted by the first optoelectronic semiconductor chip.

In one embodiment of the optoelectronic component, an individual parameter of the first optoelectronic semiconductor chip is stored in the electronic semiconductor chip. The electronic semiconductor chip can be configured to drive the first optoelectronic semiconductor chip depending on the individual parameter. The individual parameter can be for example a luminosity of the first optoelectronic semiconductor chip. Advantageously, when driving the first optoelectronic semiconductor chip, the electronic semiconductor chip can then take account of individual properties of the first optoelectronic semiconductor chip. By way of example, the electronic semiconductor chip can drive the first optoelectronic semiconductor chip such that the brightness actually emitted by the first optoelectronic semiconductor chip has a desired value.

In this case, the electronic semiconductor chip can for example also take account of aging effects of the first optoelectronic semiconductor chip.

In one embodiment of the optoelectronic component, a contact side of the first optoelectronic semiconductor chip and a contact side of the electronic semiconductor chip are oriented at an angle different than 0° with respect to one another. By way of example, the contact side of the first optoelectronic semiconductor chip and the contact side of the electronic semiconductor chip can be arranged at an angle of 90°. As a result, the electronic semiconductor chip can be oriented for example parallel to a mounting plane of the optoelectronic component, while the first optoelectronic semiconductor chip is oriented perpendicular to the mounting plane of the optoelectronic component. This enables a compact and space-saving configuration of the optoelectronic component and at the same time allows the optoelectronic component to emit electromagnetic radiation in a direction parallel to the mounting plane.

In one embodiment of the optoelectronic component, a second optoelectronic semiconductor chip is arranged in the cavity of the first molded body. The first optoelectronic semiconductor chip and the second optoelectronic semiconductor chip can be configured for example to emit electromagnetic radiation having different wavelengths. In this case, the optoelectronic component can advantageously emit light having a mixed color and/or light having an adjustable color.

A method for producing an optoelectronic component comprises a step for forming a first molded body and a second molded body, which is separate from the first molded body. In this case, a first leadframe section of a leadframe is embedded in some sections into the first molded body and in some sections into the second molded body.

Advantageously, the separate molded bodies of the optoelectronic component obtainable by this method can be oriented differently. In this case, the two molded bodies can advantageously nevertheless be produced in common processing steps.

In one embodiment of the method, the latter comprises a further step for bending the first leadframe section in such a way that a bend is formed between the first molded body and the second molded body. This allows the second molded body to be arranged at an angle relative to the first molded body. A further advantage of the production method mentioned is that the first molded body and the second molded body can be processed jointly before the bending of the first leadframe section.

In one embodiment of the method, the first molded body is formed with a cavity. In this case, after forming the first molded body, a further step is carried out for arranging a first optoelectronic semiconductor chip in the cavity. This method advantageously allows the first molded body to be oriented such that electromagnetic radiation emitted by the first optoelectronic semiconductor chip is emitted in a desired spatial direction.

In one embodiment of the method, the latter comprises a further step for arranging an electronic semiconductor chip in or on the second molded body. In the case of the optoelectronic component obtainable by the method, the electronic semiconductor chip can serve for example to drive the first optoelectronic semiconductor chip. The arrangement of the electronic semiconductor chip in or on the second molded body advantageously allows the first molded body of the optoelectronic component obtainable by the method to be formed with compact exterior dimensions.

A further advantage of the production method mentioned is that arranging the first optoelectronic semiconductor chip in the cavity of the first molded body and arranging the electronic semiconductor chip in or on the second molded body and also electrically contacting the first optoelectronic semiconductor chip and the electronic semiconductor chip can be carried out in common processing steps.

In one embodiment of the method, the latter comprises further steps for determining an individual parameter of the first optoelectronic semiconductor chip and for storing the individual parameter in the electronic semiconductor chip. In this case, the individual parameter can be for example a luminosity of the first optoelectronic semiconductor chip and can be determined by means of a measurement, for example. The individual parameter can be stored for example in a volatile or nonvolatile data memory of the electronic semiconductor chip. The method can enable the electronic semiconductor chip of the optoelectronic component obtainable by the method for example to drive the first optoelectronic semiconductor chip depending on the individual parameter.

The above-described properties, features and advantages of this invention and the way in which they are achieved will become clearer and more clearly understood in association with the following description of the exemplary embodiments which are explained in greater detail in association with the drawings. Here in a schematic illustration in each case:

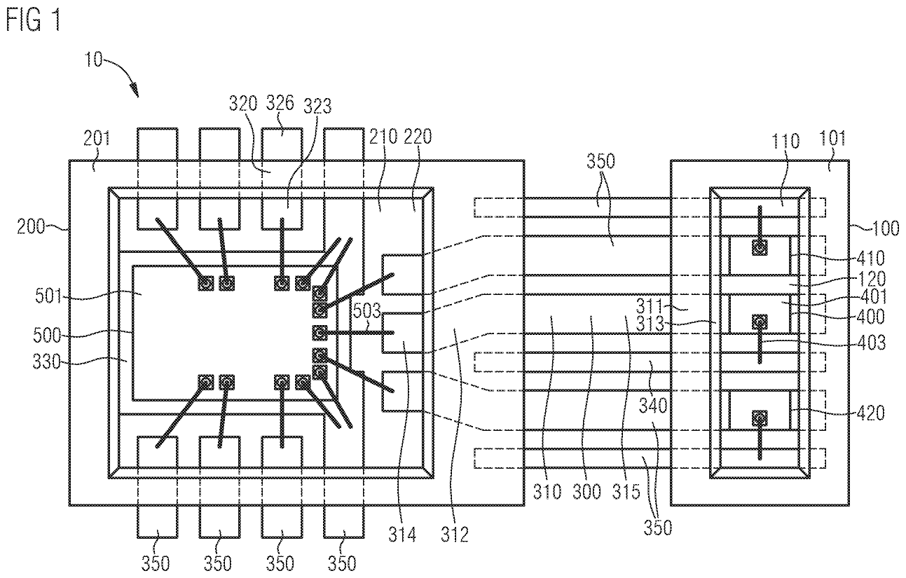

FIG. 1 shows a plan view of an optoelectronic component;

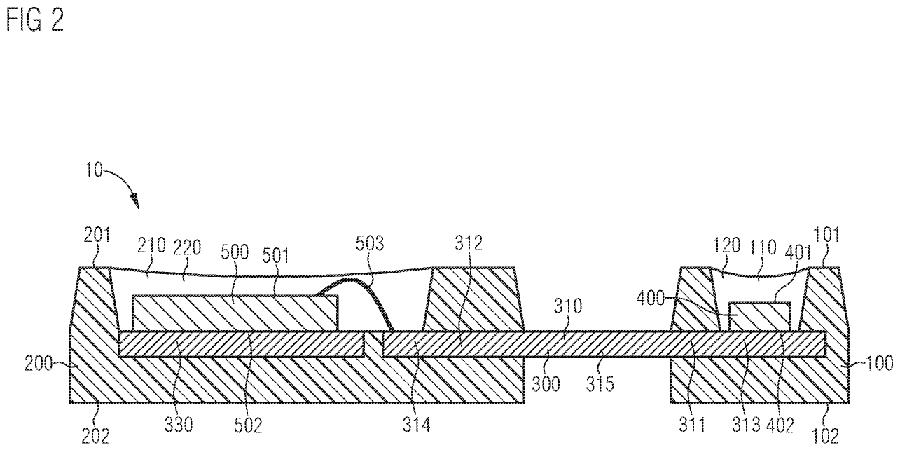

FIG. 2 shows a sectional side view of the optoelectronic component;

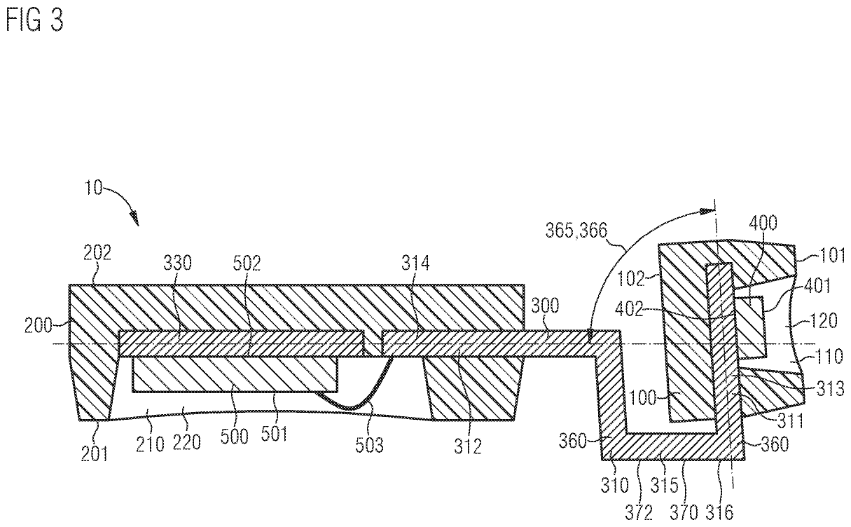

FIG. 3 shows a sectional side view of the optoelectronic component in a subsequent processing state;

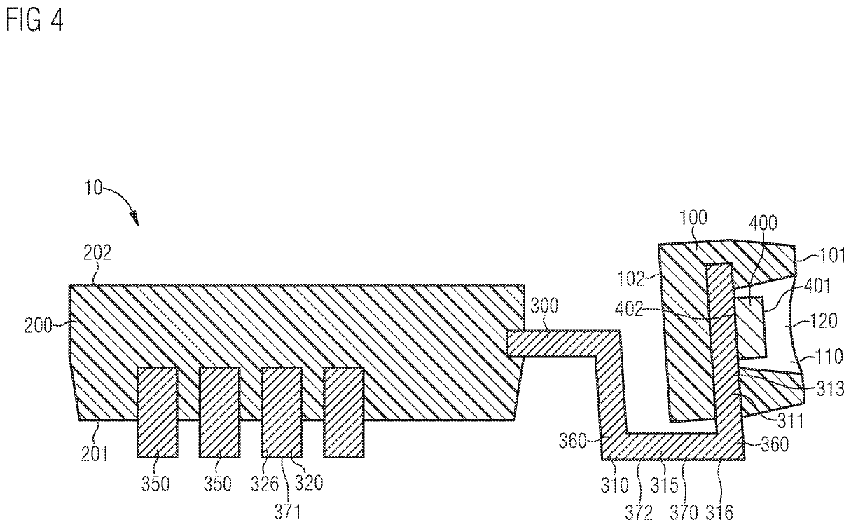

FIG. 4 shows a side view of the optoelectronic component;

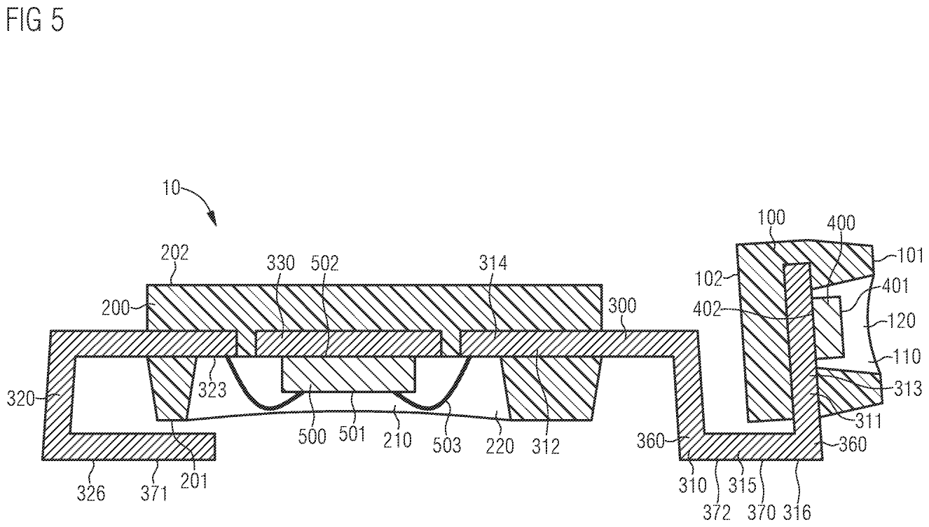

FIG. 5 shows a sectional side view of another variant of the optoelectronic component;

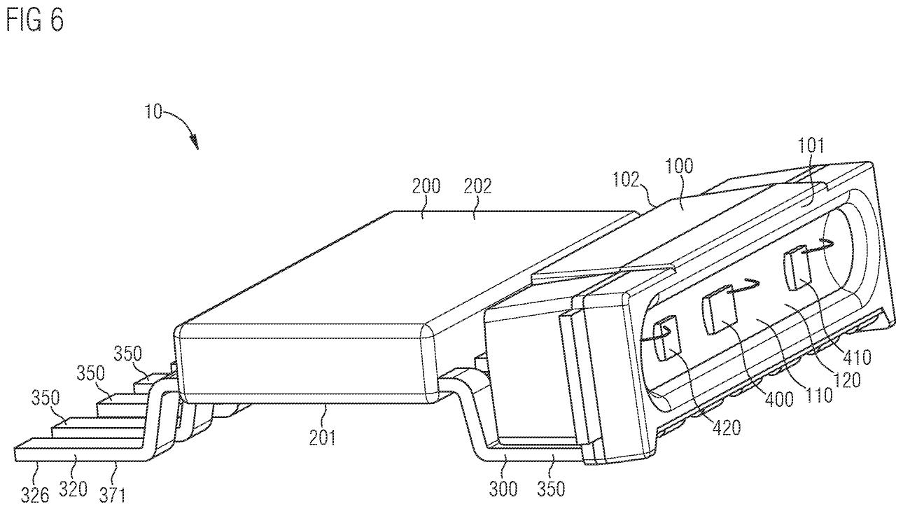

FIG. 6 shows a perspective illustration of a further variant of the optoelectronic component; and

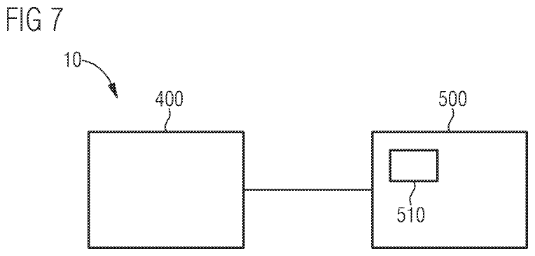

FIG. 7 shows a block diagram of the optoelectronic component.

FIG. 1 shows, in a schematic illustration, a plan view of an optoelectronic component 10 in an as yet unfinished processing state. FIG. 2 shows a schematic sectional side view of the optoelectronic component 10 in the same processing state.

The optoelectronic component 10 comprises a leadframe 300 comprising a first leadframe section 310, a second leadframe section 320, a third leadframe section 330, a fourth leadframe section 340 and a plurality of further leadframe sections 350. The configuration of the leadframe 300 shown in FIGS. 1 and 2 is merely by way of example. The leadframe 300 can also comprise a different number of leadframe sections. The leadframe sections can also be formed differently than the illustration shown in FIGS. 1 and 2.

The leadframe 300 comprises an electrically conductive material, for example a metal. The leadframe 300 has a substantially flat and planar shape in the processing state shown in FIGS. 1 and 2. In this case, the individual leadframe sections 310, 320, 330, 340, 350 of the leadframe 300 are arranged next to one another in a common plane. The leadframe 300 can be fabricated from a thin metal sheet, for example.

Moreover, the optoelectronic component 10 comprises a first molded body 100 and a second molded body 200, which is separate from the first molded body 100. The first molded body 100 and the second molded body 200 have been produced from a molding material (mold material) by a molding method (mold method). The molding material can be an epoxy, for example.

During the production of the first molded body 100 and the second molded body 200, the leadframe sections 310, 320, 330, 340, 350 of the leadframe 300 have been partly embedded into the first molded body 100 and into the second molded body 200 by virtue of the molding material of the first molded body 100 and of the second molded body 200 having been molded in some sections around the leadframe sections 310, 320, 330, 340, 350 of the leadframe 300. In this case, the first molded body 100 and the second molded body 200 have been formed separately in such a way that the first molded body 100 and the second molded body 200 are spaced apart from one another and are connected to one another only via the leadframe 300. The molding material of the first molded body 100 and the molding material of the second molded body 200 are thus not directly connected to one another.

The first leadframe section 310 of the leadframe 300 is embedded in some sections into the first molded body 100 and in some sections into the second molded body 200. A first embedded section 311 of the first leadframe section 310 is embedded into the first molded body 100. A second embedded section 312 of the first leadframe section 310, said second embedded section being spaced apart from the first embedded section 311, is embedded into the second molded body 200. The first leadframe section 310 of the leadframe 300 thus has sections which are arranged between the first embedded section 311 and the second embedded section 312 and which are embedded neither into the first molded body 100 nor into the second molded body 200. The first leadframe section 310 thus additionally connects the first molded body 100 and the second molded body 200 of the optoelectronic component 10 to one another. The first embedded section 311 and the second embedded section 312 are oriented parallel to one another in the processing state shown in FIGS. 1 and 2.

The second leadframe section 320 of the leadframe 300 is embedded in some sections into the second molded body 200, but is not embedded into the first molded body 100. The third leadframe section 330, too, is embedded only into the second molded body 200, but not into the first molded body 100. By contrast, the fourth leadframe section 340 is embedded both in some sections into the first molded body 100 and in some sections into the second molded body 200. The further leadframe sections 350 of the leadframe 300 are each either embedded only in some sections into the second molded body 200 or embedded in some sections both into the first molded body 100 and in some sections into the second molded body 200. It would also be possible for the leadframe 300 to comprise further leadframe sections which are only embedded in some sections into the first molded body 100, but are not embedded into the second molded body 200.

The first molded body 100 has a top side 101 and an underside 102 situated opposite the top side 101. A first cavity 110 is formed on the top side 101 of the first molded body 100. The parts of the leadframe sections 310, 340, 350 of the leadframe 300 that are embedded into the first molded body 100 are partly exposed in the first cavity 110. In this regard, a surface of a first inner contact section 313 of the first embedded section 311 of the first leadframe section 110 of the leadframe 300 is exposed in the first cavity 310.

A first optoelectronic semiconductor chip 400 is arranged in the first cavity 110 of the first molded body 100. The first optoelectronic semiconductor chip 400 is configured to emit electromagnetic radiation, for example visible light. The first optoelectronic semiconductor chip 400 can be for example a light emitting diode chip (LED chip). The first optoelectronic semiconductor chip 400 has a top side 401 and a contact side 402 situated opposite the top side 401. The first optoelectronic semiconductor chip 400 is configured to emit electromagnetic radiation at its top side 401 in a main emission direction perpendicular to the top side 401.

The first optoelectronic semiconductor chip 400 is electrically conductively connected to the first leadframe section 310 and to the fourth leadframe section 340 of the leadframe 300. In the example shown in FIGS. 1 and 2, the first optoelectronic semiconductor chip 400 is arranged on the first inner contact section 313 of the first leadframe section 310 in such a way that the contact side 402 of the first optoelectronic semiconductor chip 400 faces the first inner contact section 313 of the first leadframe section 310 and is electrically conductively connected to the first inner contact section 313 of the first leadframe section 310. As a result, the contact side 402 of the first optoelectronic semiconductor chip 400 is oriented parallel to the surface of the first inner contact section 313 of the first leadframe section 310. The top side—parallel to the contact side 402—of the first optoelectronic semiconductor chip 400 is oriented in the same direction as the top side 101 of the first molded body 100. The electrically conductive connection between the first optoelectronic semiconductor chip 400 and the fourth leadframe section 340 is produced by a bond wire 403 in the example shown in FIGS. 1 and 2.

In addition to the first optoelectronic semiconductor chip 400, a second optoelectronic semiconductor chip 410 and a third optoelectronic semiconductor chip 420 are also arranged in the first cavity 110 of the first molded body 100. The second optoelectronic semiconductor chip 410 and the third optoelectronic semiconductor chip 420 are electrically conductively connected to further leadframe sections 350 of the leadframe 300. The second optoelectronic semiconductor chip 410 and the third optoelectronic semiconductor chip 420 are likewise configured to emit electromagnetic radiation, for example visible light. The second optoelectronic semiconductor chip 410 and the third optoelectronic semiconductor chip 420 can be configured for example as light emitting diode chips (LED chips). The first optoelectronic semiconductor chip 400, the second optoelectronic semiconductor chip 410 and the third optoelectronic semiconductor chip 420 can be configured to emit light having wavelengths from respectively different spectral ranges. By way of example, the first optoelectronic semiconductor chip 400 can be configured to emit light having a wavelength from the green spectral range. The second optoelectronic semiconductor chip 410 can be configured for example to emit light having a wavelength from the red spectral range. The third optoelectronic semiconductor chip 420 can be configured for example to emit light having a wavelength from the blue spectral range. The optoelectronic semiconductor chips 400, 410, 420 can also be equipped with wavelength-converting elements provided for at least partly converting light emitted by the respective optoelectronic semiconductor chip 400, 410, 420 into light having a different wavelength. It is also possible for fewer than three or more than three optoelectronic semiconductor chips 400, 410, 420 to be arranged in the first cavity 110 of the first molded body 100 of the optoelectronic component 10.

The second molded body 200 has a top side 201 and an underside 202 situated opposite the top side 201. In the processing state of the optoelectronic component 10 shown in FIGS. 1 and 2, the first molded body 100 and the second molded body 200 are arranged parallel to one another in such a way that the top side 101 of the first molded body 100 and the top side 201 of the second molded body 200 are oriented parallel to one another. Moreover, the underside 102 of the first molded body 100 and the underside 202 of the second molded body 200 are oriented parallel to one another.

A second cavity 210 is formed on the top side 201 of the second molded body 200. Surfaces of those parts of the leadframe sections 310, 320, 330, 350 of the leadframe 300 which are embedded into the second molded body 200 are exposed in the second cavity 210. By way of example, a surface of a second inner contact section 314 of the second embedded section 312 of the first leadframe section 310 of the leadframe 300 is exposed in the second cavity 210. Moreover, an inner contact section 323 of the second leadframe section 320 is exposed in the second cavity 210.

An electronic semiconductor chip 500 is arranged in the second cavity 210 of the second molded body 200. The electronic semiconductor chip 500 can also be referred to as an integrated circuit (IC). The electronic semiconductor chip 500 can be configured for example as a driver chip for driving the first optoelectronic semiconductor chip 400, the second optoelectronic semiconductor chip 410 and/or the third optoelectronic semiconductor chip 420.

The electronic semiconductor chip 500 has a top side 501 and a contact side 502 situated opposite the top side 501. In the example shown in FIGS. 1 and 2, the electronic semiconductor chip 500 is arranged on the third leadframe section 330 in such a way that the contact side 502 of the electronic semiconductor chip 500 faces the top side of the third leadframe section 330. The contact side 502 and the top side 501—parallel to the contact side 502—of the electronic semiconductor chip 500 are thus oriented parallel to the third leadframe section 330. This means that, in the processing state of the optoelectronic component 10 shown in FIGS. 1 and 2, the contact side 502 of the electronic semiconductor chip 500 is also oriented parallel to the contact side 402 of the first optoelectronic semiconductor chip 400 and the top side 501 of the electronic semiconductor chip 500 is oriented parallel to the top side 401 of the first optoelectronic semiconductor chip 400.

The electronic semiconductor chip 500 is electrically conductively connected to the second inner contact section 314 of the first leadframe section 310 of the leadframe 300 by means of a bond wire 503. The electronic semiconductor chip 500 is thus also electrically conductively connected to the first optoelectronic semiconductor chip 400. Moreover, in the example shown in FIGS. 1 and 2, the electronic semiconductor chip 500 is electrically conductively connected to the inner contact section 323 of the second leadframe section 320, to the third leadframe section 330 and to further leadframe sections 350 by means of further bond wires.

After the process of forming the first molded body 100, the first optoelectronic semiconductor chip 400, the second optoelectronic semiconductor chip 410 and the third optoelectronic semiconductor chip 420 can have been arranged in the first cavity 110 of the first molded body 100 and electrically conductively connected to the leadframe sections 310, 340, 350 of the leadframe 300. Afterward, a first potting 120 can also have been arranged in the first cavity 110. The first potting 120 can comprise a silicone, for example, and expediently has a high transparency for electromagnetic radiation emitted by the optoelectronic semiconductor chips 400, 410, 420. The optoelectronic semiconductor chips 400, 410, 420 arranged in the first cavity 110 are embedded into the first potting 120 and thereby protected against damage resulting from external influences. However, the first potting 120 can also be omitted.

After the process of forming the second molded body 200, the electronic semiconductor chip 500 can have been arranged in the second cavity 210 and electrically conductively connected to the leadframe sections 310, 320, 330, 350 of the leadframe 300. The process of arranging the electronic semiconductor chip 500 in the second cavity 210 of the second molded body 200 can be carried out for example in a common processing step with the arrangement of the electronic semiconductor chips 400, 410, 420 in the first cavity 110 of the first molded body 100. The process of producing the electrically conductive connections can also be carried out in a common processing procedure in the case of the optoelectronic semiconductor chips 400, 410, 420 and the electronic semiconductor chip 500. Afterward, a second potting 220 can be arranged in the second cavity 210 of the second molded body 200, into which the electronic semiconductor chip 500 is embedded in order to protect the electronic semiconductor chip 500 against damage resulting from external influences. However, the second potting 220 can also be omitted.

In an alternative production method, as early as before the process of forming the first molded body 100 and the second molded body 200, the electronic semiconductor chip 500 is arranged on the third leadframe section 330 of the leadframe 300 and electrically conductively connected to the leadframe sections 310, 320, 330, 350 of the leadframe 300. The electronic semiconductor chip 500 is then embedded into the second molded body 200 during the process of forming the first molded body 100 and the second molded body 200. In this variant of the production method, the second molded body 200 need not have the second cavity 210.

FIG. 3 shows a schematic sectional side view of the optoelectronic component 10 in a processing state temporally succeeding the illustration in FIGS. 1 and 2. FIG. 4 shows a further side view of the optoelectronic component 10 in the processing state shown in FIG. 3. In FIG. 4, only the first molded body 100 is illustrated in a sectional view, while the second molded body 200 is shown in an exterior view. The production of the optoelectronic component 10 can be concluded in the processing state shown in FIGS. 3 and 4.

Proceeding from the processing state shown in FIGS. 1 and 2, the regions of the leadframe 300 arranged between the first molded body 100 and the second molded body 200 have been bent over. In a bending section 315 arranged between the first molded body 100 and the second molded body 200, the first leadframe section 310 has been bent over in such a way that at least one bend 360 at which the direction of extent of the first leadframe section 310 changes has been formed in the bending section 315. In the example shown in FIGS. 3 and 4, two bends 360 have been formed in the bending section 315 of the first leadframe section 310. The other leadframe sections 340, 350 of the leadframe 300 extending between the first molded body 100 and the second molded body 200 have been bent in the same way.

As a result of the bending of the parts of the leadframe 300 arranged between the first molded body 100 and the second molded body 200, the first molded body 100 and the second molded body 200 are no longer oriented parallel to one another in the processing state shown in FIGS. 3 and 4. Accordingly, the first embedded section 311—enclosed into the first molded body 100—of the first leadframe section 310 of the leadframe 300 is also no longer oriented parallel to the second embedded section 312—enclosed into the second molded body 200—of the first leadframe section 310. Instead, the first embedded section 311 and the second embedded section 312 of the first leadframe section 310 form a leadframe angle 365 different than 0°, which angle is somewhat less than 90° in the example shown in FIGS. 3 and 4, but can also be exactly 90° or have some other value between 0° and 180°. Accordingly, the contact side 402 of the first optoelectronic semiconductor chip 400 and the contact side 502 of the electronic semiconductor chip 500 also form a chip angle 366 corresponding to the leadframe angle 365. If the chip angle 366 has a value of 90°, then the top side 401 of the first optoelectronic semiconductor chip 400 and thus also the main emission direction of the first optoelectronic semiconductor chip 400 are oriented perpendicular to the top side 501 of the electronic semiconductor chip 500.

An outer contact section 316 of the first leadframe section 310, said outer contact section being arranged in the bending section 315 between the two bends 360 of the first leadframe section 310 of the leadframe 300 between the first molded body 100 and the second molded body 200, forms a first soldering contact 370 of the optoelectronic component 10. A corresponding outer contact section of the fourth leadframe section 340, said outer contact section being arranged between the first molded body 100 and the second molded body 200, forms a third soldering contact 372 of the optoelectronic component 10. The further leadframe sections 350 extending between the first molded body 100 and the second molded body 200 of the optoelectronic component 10 also have corresponding outer contact sections that form further soldering contacts of the optoelectronic component 10.

An outer contact section 326 of the second leadframe section 320, said outer contact section being arranged outside the second molded body 200, has also been bent over in a processing step temporally succeeding the illustration in FIGS. 1 and 2.

In this case, the outer contact section 326 has been bent over in the direction toward the top side 201 of the second molded body 200 in such a way that the outer contact section 326 projects beyond the top side 201 of the second molded body 200 in the processing stage shown in FIGS. 3 and 4. The further leadframe sections 350 of the leadframe 300 which are embedded only into the second molded body 200, but are not embedded into the first molded body 100, have been bent in an analogous manner.

The outer contact section 326 of the second leadframe section 320 projecting beyond the top side 201 of the second molded body 200 forms a second soldering contact 371 of the optoelectronic component 10. Outer contact sections of the further leadframe sections 350 which are embedded only into the second molded body 200, but not into the first molded body 100, form further soldering contacts of the optoelectronic component 10.

The optoelectronic component 10 can be provided for surface mounting. In this case, the first soldering contact 370, the second soldering contact 371, the third soldering contact 372 and the further soldering contacts of the optoelectronic component 10 are secured at a surface by means of a soldering method, for example by reflow soldering, in such a way that the top side 201 and the underside 202 of the second molded body 200, the top side 501 and the contact side 502 of the electronic semiconductor chip 500 and the second embedded section 312 of the first leadframe section 310 are oriented parallel to the surface. The main emission direction of the first optoelectronic semiconductor chip 400 perpendicular to the top side 401 of the first optoelectronic semiconductor chip 400 is then tilted by the chip angle 366 relative to the surface.

The second soldering contact 371 and the third soldering contact 372 can serve for electrically contacting the optoelectronic component 10. The first soldering contact 370 can optionally likewise serve for electrically contacting the optoelectronic component 10. Alternatively, however, the first soldering contact 370 can also serve only for mechanically securing the optoelectronic component 10. Soldering contacting of the first soldering contact 370 can also be dispensed with.

FIG. 5 shows a schematic sectional side view of an alternative configuration of the optoelectronic component 10.

FIG. 6 shows a schematic perspective illustration of yet another configuration of the optoelectronic component 10.

The variants of the optoelectronic component 10 that are shown in FIGS. 5 and 6 differ from the variant of the optoelectronic component 10 that is shown in FIGS. 3 and 4 by virtue of the fact that, in the case of the variants of the optoelectronic component 10 that are shown in FIGS. 5 and 6, the leadframe sections 320, 330, 350 of the leadframe 300 that are embedded only into the second molded body 200, but not into the first molded body 100, project from the second molded body 200 at an end side facing away from the first molded body 100, while in the case of the variant of the optoelectronic component 10 that is shown in FIGS. 3 and 4, said leadframe sections project at those sides of the second molded body 200 which are parallel to the connecting direction between the first molded body 100 and the second molded body 200.

The variants of the optoelectronic component 10 that are shown in FIGS. 5 and 6 differ by virtue of the fact that, in the case of the variant shown in FIG. 5, the outer contact sections of the leadframe sections 320, 330, 350 projecting from the second molded body 200 at the end side of the second molded body 200 facing away from the first molded body 100 have been bent over in the direction toward the first molded body 100 and are thus arranged over the top side 201 of the second molded body 200, while in the case of the variant shown in FIG. 6, said contact sections have been bent over in the direction pointing away from the first molded body 100.

The optoelectronic component 10 can be produced jointly with further optoelectronic components 10 of identical type in common processing steps. In this case, the leadframes 300 of the individual optoelectronic components 10 are firstly partly connected to one another and are separated only after the molded bodies 100, 200 have been formed. The separating can be carried out before or at the same time as the bending over of the leadframe sections 310, 320, 330, 340, 350.

FIG. 7 shows a highly schematic block diagram of the optoelectronic component 10. The electronic semiconductor chip 500 of the optoelectronic component 10 can be configured to drive the first optoelectronic semiconductor chip 400, and is electrically conductively connected to the first optoelectronic semiconductor chip 400 for this purpose.

An individual parameter 510 of the first optoelectronic semiconductor chip 400 can be stored in the electronic semiconductor chip 500. The individual parameter 510 specifies an individual characteristic of the first optoelectronic semiconductor chip 400. The individual parameter 510 can be for example a luminosity of the first optoelectronic semiconductor chip 400. The individual parameter 510 of the first optoelectronic semiconductor chip 400 can have been determined by a measurement and subsequently stored in the electronic semiconductor chip 500 after the production of the optoelectronic component 10. For this purpose, the electronic semiconductor chip 500 can have a volatile or nonvolatile data memory.

The electronic semiconductor chip 500 can be configured to drive the first optoelectronic semiconductor chip 400 depending on the individual parameter 510. If the individual parameter 510 specifies for example a luminosity of the first optoelectronic semiconductor chip 400, the electronic semiconductor chip 500 can be configured such that the first optoelectronic semiconductor chip 400 is driven depending on the individual parameter 510 such that a brightness of electromagnetic radiation emitted by the first optoelectronic semiconductor chip 400 corresponds to a desired target value.

The invention has been illustrated and described in more specific detail on the basis of the preferred exemplary embodiments. Nevertheless, the invention is not restricted to the examples disclosed. Rather, other variations can be derived therefrom by a person skilled in the art, without departing from the scope of protection of the invention.

### LIST OF REFERENCE SIGNS

10 Optoelectronic component
100 First molded body
101 Top side
102 Underside
110 First cavity
120 First potting
200 Second molded body
201 Top side
202 Underside
210 Second cavity
220 Second potting
300 Leadframe
310 First leadframe section
311 First embedded section
312 Second embedded section
313 First inner contact section
314 Second inner contact section
315 Bending section
316 Outer contact section
320 Second leadframe section
323 Inner contact section
326 Outer contact section
330 Third leadframe section
340 Fourth leadframe section
350 Further leadframe section
360 Bend
365 Leadframe angle
366 Chip angle
370 First soldering contact
371 Second soldering contact
372 Third soldering contact
400 First optoelectronic semiconductor chip
401 Top side
402 Contact side
403 Bond wire
410 Second optoelectronic semiconductor chip
420 Third optoelectronic semiconductor chip
500 Electronic semiconductor chip
501 Top side
502 Contact side
503 Bond wire
510 Individual parameter

1. An optoelectronic component
comprising a first molded body and a second molded body, which is separate from the first molded body, and comprising a leadframe comprising a first leadframe section,
wherein the first leadframe section is embedded in some sections into the first molded body and in some sections into the second molded body,
wherein the first molded body has a cavity,
wherein a first optoelectronic semiconductor chip is arranged in the cavity,
wherein an electronic semiconductor chip is arranged in or on the second molded body,
wherein the first optoelectronic semiconductor chip and the electronic semiconductor chip are each electrically conductively connected to the first leadframe section,
wherein the electronic semiconductor chip is configured to drive the first optoelectronic semiconductor chip.

2. The optoelectronic component as claimed in claim 1,
wherein the first leadframe section has at least one bend between the first molded body and the second molded body.

3. The optoelectronic component as claimed in claim 1,
wherein a first section of the first leadframe section, said first section being embedded into the first molded body, and a second section of the first leadframe section, said second section being embedded into the second molded body, are oriented at an angle different than 0° with respect to one another, in particular an angle of 90°.

4. The optoelectronic component as claimed in claim 1,
wherein a contact section of the first leadframe section, said contact section being arranged between the first molded body and the second molded body, forms a first soldering contact of the optoelectronic component.

5. The optoelectronic component as claimed in claim 1,
wherein a second leadframe section of the leadframe is embedded in some sections into the second molded body but is not embedded into the first molded body.

6. The optoelectronic component as claimed in claim 5,
wherein a contact section of the second leadframe section forms a second soldering contact of the optoelectronic component.

7-10. (canceled)

11. The optoelectronic component as claimed in claim 1,
wherein an individual parameter of the first optoelectronic semiconductor chip is stored in the electronic semiconductor chip.

12. The optoelectronic component as claimed in claim 11,
wherein the electronic semiconductor chip is configured to drive the first optoelectronic semiconductor chip depending on the individual parameter.

13. The optoelectronic component as claimed in claim 11,
wherein the individual parameter is a luminosity of the first optoelectronic semiconductor chip.

14. The optoelectronic component as claimed in claim 11,
wherein a contact side of the first optoelectronic semiconductor chip and a contact side of the electronic semiconductor chip are arranged at an angle different than 0° with respect to one another, in particular at an angle of 90°.

15. The optoelectronic component as claimed in claim 11,
wherein a second optoelectronic semiconductor chip is arranged in the cavity.

16. A method for producing an optoelectronic component
comprising the following step:
forming a first molded body and a second molded body, which is separate from the first molded body,
wherein a first leadframe section of a leadframe is embedded in some sections into the first molded body and in some sections into the second molded body,
bending the first leadframe section in such a way that a bend is formed between the first molded body and the second molded body,
wherein the first molded body is formed with a cavity,
wherein after forming the first molded body, a first optoelectronic semiconductor chip is arranged in the cavity,
arranging an electronic semiconductor chip in or on the second molded body.

17-19. (canceled)

20. The method as claimed in claim 16,
wherein the method comprises the following further steps:
determining an individual parameter of the first optoelectronic semiconductor chip;
storing the individual parameter in the electronic semiconductor chip.
